(19) United States
(12) Patent Application Publication
(10) Pub. No.: US 2025/0234663 A1
(43) Pub. Date: Jul. 17, 2025

(54) IMAGE SENSING DEVICE AND METHOD FOR MANUFACTURING THE SAME

(71) Applicant: SK hynix Inc., Icheon-si (KR)

(72) Inventors: Da Yea BAEK, Icheon-si (KR); Hyun Soo LIM, Icheon-si (KR)

(21) Appl. No.: 18/757,262

(22) Filed: Jun. 27, 2024

(30) Foreign Application Priority Data
Jan. 12, 2024 (KR) 10-2024-0005308

(51) Int. Cl. H01L 27/146

(52) U.S. Cl. CPC H10F 39/807; H10F 39/011

(57) ABSTRACT

An image sensing device is provided to include: a substrate; a photoelectric conversion element formed in the substrate; an isolation structure disposed between the photoelectric conversion element and an additional photoelectric conversion element disposed adjacent to the photoelectric conversion element; a floating diffusion region disposed above an upper portion of the isolation structure; and a floating diffusion region protecting layer disposed below the floating diffusion region and contacting the upper portion of the isolation structure.

### CROSS-REFERENCE TO RELATED APPLICATION(S)

This patent document claims the priority and benefits of Korean Patent Application No. 10-2024-0005308, filed on Jan. 12, 2024, which is incorporated by reference in its entirety as part of the disclosure of this patent document.

### TECHNICAL FIELD

Various embodiments of the disclosed technology relate to an image sensing device and a method for manufacturing the same.

### BACKGROUND

An image sensing device refers to a semiconductor device that captures and converts an optical image to electrical signals. With the development of automobile, medical, computer and telecommunication industries, the demand for high-performance image sensing devices is increasing in various devices such as smart phones, digital cameras, game devices, Internet of Things, robots, security cameras, and medical micro-cameras.

The most common types of image sensing devices are charge coupled device (CCD) image sensing devices and complementary metal oxide semiconductor (CMOS) image sensing devices.

### SUMMARY

The disclosed technology can be implemented in various implementations to provide an image sensing device and a manufacturing method thereof, which are capable of improving a process variation and pixel uniformity by preventing the floating diffusion region from being etched during a trench forming process.

In one aspect, an image sensing device is provided to include: a substrate; a photoelectric conversion element formed in the substrate; an isolation structure disposed between the photoelectric conversion element and an additional photoelectric conversion element disposed adjacent to the photoelectric conversion element; a floating diffusion region disposed above an upper portion of the isolation structure; and a floating diffusion region protecting layer disposed below the floating diffusion region and contacting the upper portion of the isolation structure.

In some implementations, the floating diffusion region protecting layer may include at least one of an oxide or a nitride.

In some implementations, a transfer transistor may be disposed over the floating diffusion region.

In some implementations, the upper portion of the isolation structure may be disposed to contact one region of the floating diffusion region protecting layer.

In some implementations, a width of the floating diffusion region protecting layer may be greater than a width of the isolation structure.

In some implementations, a width of the floating diffusion region protecting layer may be greater than or equal to a width of the floating diffusion region.

In some implementations, a height of the isolation structure may be greater than a height of the floating diffusion region.

In some implementations, a width of the floating diffusion region protecting layer may be greater than a width of the isolation structure and smaller than a width of the floating diffusion region.

In some implementations, the floating diffusion region protecting layer may be formed above an upper portion of one side of the photoelectric conversion element.

In some implementations, the substrate may have an etch selectivity that is different from an etch selectivity of the protecting layer.

In another aspect, a method for manufacturing an image sensing device is provided. The method for manufacturing an image sensing device may include forming a first substrate; forming a protecting layer on the first substrate; etching one region of the protecting layer; forming a second substrate on the protecting layer; forming a floating diffusion region in the second substrate; and forming a transfer transistor above the floating diffusion region.

In some implementations, the method may further include forming an isolation structure below the floating diffusion region protecting layer.

In some implementations, the floating diffusion region protecting layer may include at least one or an oxide or a nitride.

In some implementations, the forming of the floating diffusion region protecting layer may include depositing material to form the isolation structure; and etching a portion of the isolation structure.

In some implementations, an upper portion of the isolation structure may be disposed to contact one region of the floating diffusion region protecting layer.

In some implementations, the forming of the isolation structure may include etching the first substrate.

### BRIEF DESCRIPTION OF THE DRAWINGS

FIG. 1 is a block diagram of an image sensing device according to an embodiment of the disclosed technology.

FIGS. 2 and 3 are views for illustrating a unit pixel of an image sensing device according to an embodiment of the disclosed technology.

FIG. 4 is a cross sectional view of A-A′ part of FIG. 3.

FIGS. 5 to 10 are views for describing a method for manufacturing an image sensing device according to an embodiment of the disclosed technology.

### DETAILED DESCRIPTION

Features, and certain advantages in connection with specific implementations of the disclosed technology disclosed in this patent document are described by example embodiments with reference to the accompanying drawings.

As a size of a pixel of the image sensing device decreases, an area ratio occupied by a photodiode in one pixel is increasing, and accordingly, a depth of a trench for blocking a crosstalk is increasing.

If the depth of the trench as formed is deep, the etching may be performed to the floating diffusion region, and thus, a problem of a pixel defect may occur.

In some implementations, a process variation and pixel uniformity may be improved by preventing a trench forming process from proceeding to etch the floating diffusion region. In some implementations, the crosstalk may be improved because the etching to a lot deeper depth can be performed without considering a margin of a crossroad region of the trench.

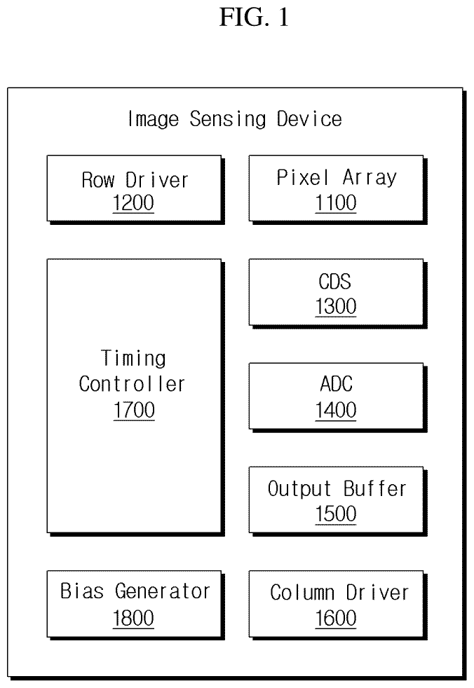

FIG. 1 is a block diagram of an image sensing device according to an embodiment.

Referring to FIG. 1, the image sensing device according to an embodiment may include a pixel array 1100, a row driver 1200, a correlate double sampler (CDS) 1300, an analog-to-digital converter (ADC) 1400, an output buffer 1500, a column driver 1600, a timing controller 1700, and a bias generator 1800. Here, the components of the image sensing device are discussed by way of example only, and at least some of the components may be added or omitted as needed.

The pixel array 1100 may include a plurality of pixels arranged in a plurality of rows and a plurality of columns. In one example, the plurality of pixels can be arranged in a two dimensional pixel array including rows and columns. In another example, the plurality of pixels can be arranged in a three dimensional pixel array. The plurality of unit pixels may convert an optical signal into an electrical signal on a unit pixel basis or a pixel group basis, where unit pixels in a pixel group share at least certain internal circuitry. The pixel array 1100 may receive driving signals, including a row selection signal, a pixel reset signal and a transmission signal, from the row driver 1200. Upon receiving the driving signal, corresponding pixels in the pixel array 1100 may be activated to perform the operations corresponding to the row selection signal, the pixel reset signal, and the transmission signal.

The row driver 1200 may activate the pixel array 1100 to perform certain operations on the imaging pixels in the corresponding row based on commands and control signals provided by the timing controller 1700. In an embodiment, the row driver 1200 may select one or more imaging pixels arranged in one or more rows of the pixel array 1100. The row driver 1200 may generate a row selection signal to select one or more rows among the plurality of rows. The row driver 1200 may sequentially enable the pixel reset signal and the transmission signal for the pixels corresponding to the at least one selected row. Thus, a reference signal and an image signal, which are analog signals generated by each of the pixels of the selected row, may be sequentially transferred to the CDS 1300. Here, the reference signal may be an electrical signal that is provided to the CDS 1300 when a sensing node (e.g., floating diffusion node) of a pixel is reset, and the image signal may be an electrical signal that is provided to the CDS 1300 when photocharges generated by the pixel are accumulated in the sensing node. The reference signal indicating unique reset noise of each pixel and the image signal indicating the intensity of incident light may be generically called a pixel signal.

CMOS image sensors may use the correlated double sampling (CDS) to remove undesired offset values of pixels known as the fixed pattern noise by sampling a pixel signal twice to remove the difference between these two samples. In one example, the correlated double sampling (CDS) may remove the undesired offset value of pixels by comparing pixel output voltages obtained before and after photocharges generated by incident light are accumulated in the sensing node so that only pixel output voltages based on the incident light can be measured. In some embodiments of the disclosed technology, the CDS 1300 may sequentially sample and hold voltage levels of the reference signal and the image signal, which are provided to each of a plurality of column lines from the pixel array 1100. That is, the CDS 1300 may sample and hold the voltage levels of the reference signal and the image signal which correspond to each of the columns of the pixel array 1100.

The CDS 1300 may transfer the reference signal and the image signal of each of the columns as a correlate double sampling signal to the ADC 1400 based on control signals from the timing controller 1700.

The ADC 140 may convert the correlate double sampling signal generated by the CDS 1300 for each of the columns into a digital signal, and output the digital signal. In some embodiment, the ADC 140 may be implemented as a ramp-compare type ADC. The ramp-compare type ADC may include a comparator circuit for comparing the analog pixel signal with a ramp signal that ramps up or down according to a time, and a timer counts until a voltage of the ramp signal matches the analog pixel signal. In some embodiments of the disclosed technology, the ADC 1400 may convert the correlate double sampling signal generated by the CDS 1300 for each of the columns into a digital signal, and output the digital signal.

The ADC 1400 may include a plurality of column counters which correspond to each of the columns of the pixel array 1100. Each column of the pixel array 1100 is connected to a column counter, and image data can be generated by converting the correlate double sampling signals which correspond to each column into digital signals using the column counter. In another embodiment of the disclosed technology, the ADC 1400 may include a global counter to convert the correlate double sampling signals corresponding to each of the columns into digital signals using a global code provided from the global counter.

The output buffer 1500 may temporarily hold the column-based image data provided from the ADC 1400 to output the image data. The image data provided to the output buffer 1500 from the ADC 1400 may be temporarily stored in the output buffer 1500 based on control signals of the timing controller 1700. The output buffer 1500 may act as an interface to compensate for data rate differences (or processing rate differences) between a data rate of the image sensing device and that of other devices connected thereto.

The column driver 1600 may select a column of the output buffer 1500 upon receiving a control signal from the timing controller 1700, and sequentially output the image data, which are temporarily stored in the selected column of the output buffer 1500. In some embodiments, the column driver 1600 may receive an address signal from the timing controller 1700, and the column driver 1600 may generate a column selection signal based on the address signal and select a column of the output buffer 1500, outputting the image data to the outside from the selected column of the output buffer 1500.

The timing controller 1700 may control at least one among the row driver 1200, the CDS 1300, the ADC 1400, the output buffer 1500, the column driver 1600, and the bias generator 1800.

The timing controller 1700 may provide at least one among the row driver 1200, the CDS 1300, the ADC 1400, the output buffer 1500, the column driver 1600, and the bias generator 1800 with a clock signal required for the operations of the respective components of the image sensing device, a control signal for timing control, address signals for selecting a row or column, and a signal for controlling a voltage level of a bias voltage applied to the pixel array 1100. In an embodiment of the disclosed technology, the timing controller 1700 may include a logic control circuit, a phase lock loop (PLL) circuit, a timing control circuit, a communication interface circuit and others.

The bias generator 1800 may generate a bias voltage for suppressing a dark current that would have been generated in a pixel of the pixel array 1100 and may apply the bias voltage to the pixel array 1100.

The bias voltage may be determined by performing a wafer probe test process of the image sensing device and stored in a one-time programmable memory (OTP) memory. For example, the bias voltage may be experimentally determined to have a value that can minimize unnecessary power consumption and maximize an effect of the dark current suppression without deteriorating performance of the image sensing device.

The bias generator 1800 may generate a voltage corresponding to a bias voltage stored in the OTP memory. In some embodiments, the OTP memory may be included in the image sensing device, and in particular, the OTP memory may be included in the bias generator 1800.

In some embodiments, the bias voltage may include a plurality of voltage values.

For example, the plurality of voltage values may correspond to a plurality of operation modes of the image sensing device, respectively. A dark current generated under a low-luminance condition may be different from a dark current generated in a high-luminance level. In order to effectively suppress the dark current in each environment, a bias voltage provided from the bias generator 1800 may vary depending on the operation mode.

In some other implementations, the plurality of values may correspond to the plurality of regions of the pixel array 1100, respectively. The dark currents generated due to the positions of the respective pixels in the pixel array 1100 may be different from each other. In order to effectively suppress the dark current regardless of the position of each pixel, the bias voltage generated by the bias generator 1800 may vary depending on the respective regions.

The bias voltage may be a negative voltage; however, the scope of the present disclosure is not limited thereto.

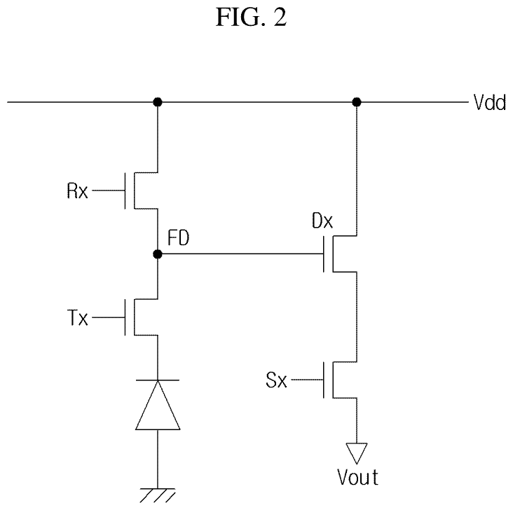

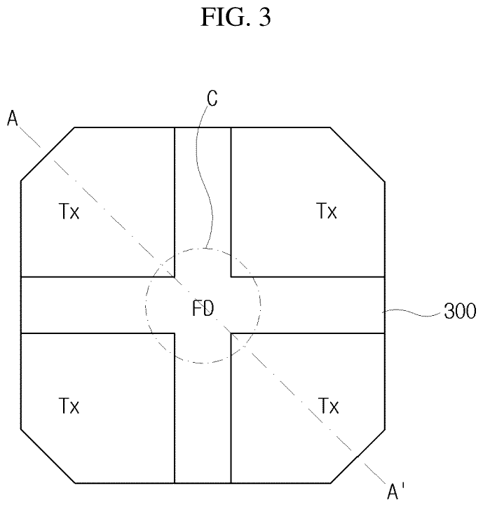

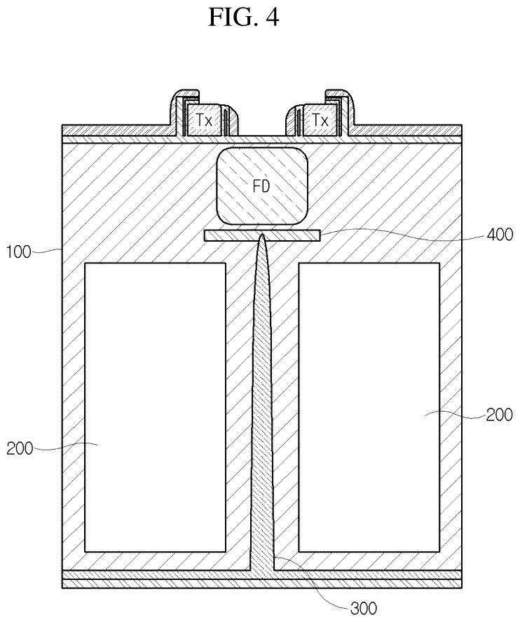

FIGS. 2 and 3 are views for illustrating the unit pixel of the image sensing device according to an embodiment. FIG. 4 is a cross sectional view taken along the line A-A′ of FIG. 3.

Referring to FIGS. 2 and 3, in an embodiment, the pixel array 1100 may include a plurality of unit pixels, and each unit pixel may include a transfer transistor TX, a floating diffusion region FD, a reset transistor RX, a drive transistor DX, a selection transistor SX, and a photodiode as an example of a photosensing device or a photoelectric conversion device. The photodiode is one example for implementing a photoelectric conversion element that is configured to convert received light into an amount of photocharge to generate and accumulate photocharge corresponding to the amount of the received incident light. While the photodiode is mentioned as one example of the photoelectric conversion element, other implementations are also possible. For example, the photoelectric conversion element may be implemented as a phototransistor, a photogate, or a pinned photodiode or a combination thereof.

The transfer transistor TX may transfer electric charges (or photoelectric currents), which are accumulated by the photodiode in response to a transfer control signal which is input into a gate, to the floating diffusion region FD.

The floating diffusion region FD may receive the charges generated by the photodiode through the transfer transistor and store the received charges.

The reset transistor RX is coupled between a power source voltage Vdd and the floating diffusion region FD, and may reset the floating diffusion region FD by draining the charges stored in the floating diffusion region FD to the power supply voltage in response to a reset signal RST.

The drive transistor DX serves as a source follower buffer amplifier, and buffers a signal corresponding to the charges which are charged in the floating diffusion region FD.

The selection transistor SX performs an addressing function and a switching function for selecting a unit pixel.

An isolation structure 300 may be formed in a lower region within the substrate 100 between two adjacent photodiodes 200 below the floating diffusion region FD and its floating diffusion region protecting layer 400 in FIG. 4 to provide isolate the two adjacent photodiodes 200. In this example in FIG. 4, two transfer transistors TX along the diagonal line A-A′ in FIG. 3 are located on the opposite sides of the FD of the unit pixel and the floating diffusion region FD and its floating diffusion region protecting layer 400 in FIG. 4 are between the transfer transistors TX.

Referring to FIGS. 3 and 4, the image sensing device according to an embodiment may include a substrate 100, a photodiode 200, the isolation structure 300, the floating diffusion region FD, and a floating diffusion region protecting layer 400.

In an embodiment, the substrate 100 may include a monocrystalline silicon-containing material.

The photodiode 200 may be formed in the substrate 100 and an n-type impurity region and a p-type impurity region may be vertically stacked in the photodiode 200. The n-type impurity region and the p-type impurity region may be formed through an ion injection process.

The isolation structure 300 may be formed between neighboring photodiodes 200, and may include at least one of a silicon oxynitride (SiON) layer, a silicon oxide (SiO) layer, a silicon nitride (SiN) layer, or polysilicon (Poly Si).

The isolation structure 300 may have a backside deep trench isolation (BDTI) structure.

The isolation structure 300 may be formed to the floating diffusion region protecting layer 400 by a difference in etch selectivity between the silicon Si of the substrate 100 and the oxide of the floating diffusion region protecting layer 400. An upper portion of the isolation structure 300 may be formed to contact one region of the floating diffusion region protecting layer 400.

In an embodiment as shown in FIG. 4, an upper end of the isolation structure 300 is located below than a lower end of the floating diffusion region FD, which is closer to the isolation structure 300 as compared to an upper end of the floating diffusion region FD. In an embodiment, a height of the isolation structure 300 may be formed to be greater than a height of the floating diffusion region FD. The height may refer to a distance between two opposite surfaces of the isolation structure 300 or the floating diffusion region FD.

The floating diffusion region FD may be formed above the isolation structure 300.

The floating diffusion region FD may be formed in a crossroad region C of the unit pixel.

The transfer transistor TX may be formed above the floating diffusion region FD.

The floating diffusion region FD may be or include the n-type impurity region.

The floating diffusion region protecting layer 400 may be formed between the floating diffusion region FD and the upper portion of the isolation structure 300.

In an embodiment, the floating diffusion region protecting layer 400 may include at least one of the oxide or the nitride. Thus, the floating diffusion region protecting layer 400 may include the oxide, the nitride, or the combination of the oxide and the nitride.

The floating diffusion region protecting layer 400 may serve to prevent the etching from attacking the floating diffusion region FD even if the etching is excessively performed without considering a margin in the crossroad region C during the etching process for forming the isolation structure 300. In the implementations, the floating diffusion region protecting layer 400 may serve to make the etching stop in the floating diffusion region protecting layer 400 even if the etching is excessively performed during the etching process for forming the isolation structure 300.

In an embodiment, a width of the floating diffusion region protecting layer 400 may be formed to be equal to or wider than a width of the floating diffusion region FD in order to prevent the floating diffusion region FD from being etched during the etching process for forming the isolation structure 300.

In an embodiment, the width of the floating diffusion region protecting layer 400 may be wider than a width of the isolation structure 300.

In an embodiment, the width of the floating diffusion region protecting layer 400 may be wider than the width of the isolation structure 300, and smaller than the width of the floating diffusion region FD.

In an embodiment, the floating diffusion region protecting layer 400 may overlap with an upper portion of one side of the photodiode 200 which is adjacent to the isolation structure 300.

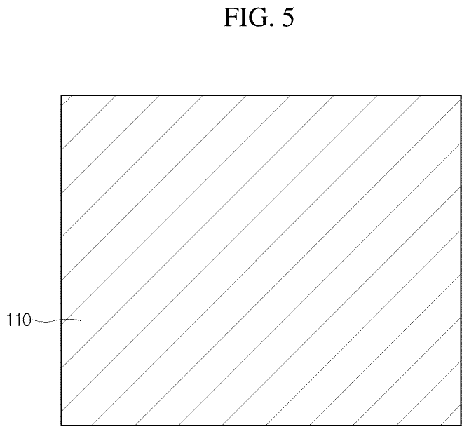

FIGS. 5 to 10 are views for describing a method for manufacturing the image sensing device according to an embodiment.

Referring to FIG. 5, the first substrate 110 may be formed through an epitaxy process.

The first substrate 110 may be a substrate which is thinned through a thinning process. In an embodiment, the first substrate 110 may be or include a bulk silicon substrate which is thinned through the thinning process. In an embodiment, the first substrate 110 may include the p-type impurities.

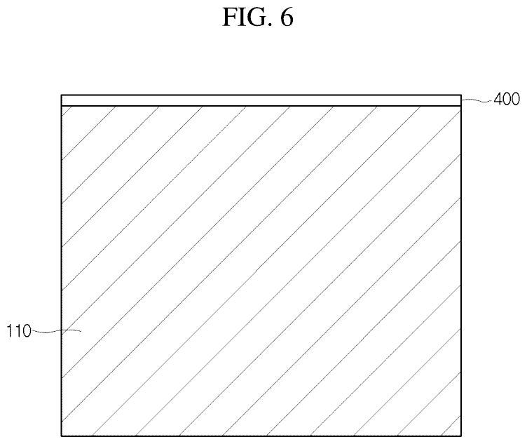

Referring to FIG. 6, the floating diffusion region protecting layer 400 may be formed through a process of depositing at least one of the oxide or the nitride on the first substrate 110. Thus, during the depositing process, the oxide, the nitride, or the combination of the oxide and the nitride is deposited on the first substrate 110.

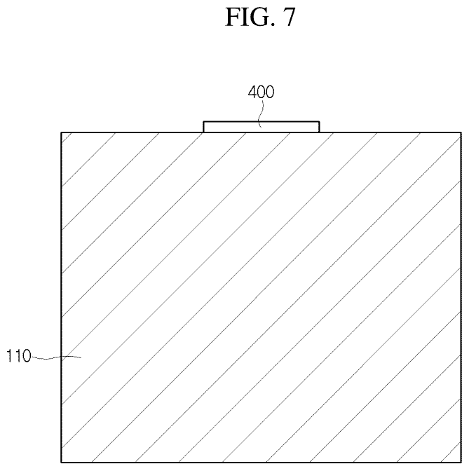

Referring to FIG. 7, the floating diffusion region protecting layer 400 in the final shape may be formed through a process of etching the remaining region of the floating diffusion region protecting layer 400 except a center region of the floating diffusion region protecting layer 400.

At this time, because it is difficult to deposit the silicon Si on the oxide, which is generally used for the floating diffusion region protecting layer 400, through the epitaxy process, the critical dimension CD of the floating diffusion region protecting layer 400 needs to be appropriately controlled so that the silicon Si, which has grown on a side of the floating diffusion region protecting layer 400, can cover the floating diffusion region protecting layer 400 sufficiently.

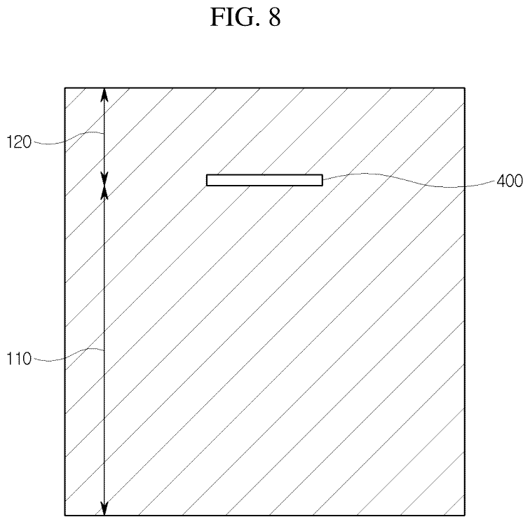

Referring to FIG. 8, through the epitaxy process, the first substrate 110 may be formed, and a second substrate 120 may be formed on the floating diffusion region protecting layer 400.

The second substrate 120 may be or include a substrate which is thinned through the thinning process. In an embodiment, the second substrate 120 may be or include a bulk silicon substrate which is thinned through the thinning process. In an embodiment, the second substrate 120 may include the p-type impurities.

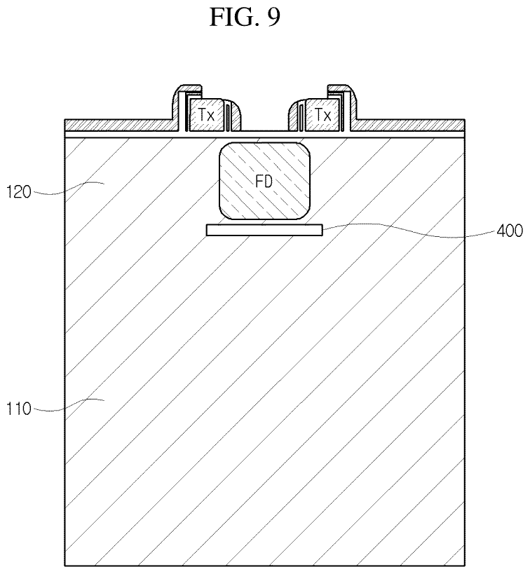

Referring to FIG. 9, the floating diffusion region FD may be formed in the second substrate 120 through the ion injection process.

The floating diffusion region FD may be formed by injecting the n-type dopant ion such as arsenic or phosphorous.

The transfer transistor TX may be formed above an upper portion of the floating diffusion region FD. The transfer transistor TX may be formed by forming a gate insulation layer (not illustrated) and a gate electrode (not illustrated) on the second substrate 120.

In an embodiment, the gate electrode (not illustrated) may include silicon oxide.

In an embodiment, the gate electrode (not illustrated) may include one selected from a group of poly-silicon, tungsten, titanium nitride, tantalum, and tantalum nitride, or a combined material thereof.

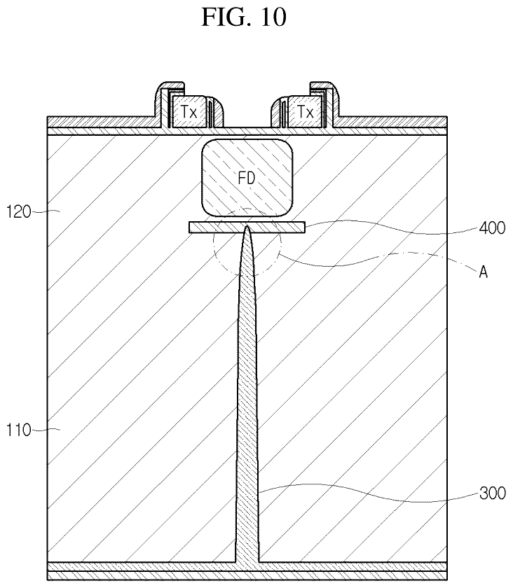

Referring to FIG. 10, the isolation structure 300 may be formed below the floating diffusion region FD. The upper portion of the isolation region may contact one region of the floating diffusion region protecting layer 400.

When etching the first substrate 110 to form the isolation structure 300, because of the difference in etch selectivity between the silicon Si and the oxide of the floating diffusion region protecting layer 400, the etching may be stopped in the floating diffusion region protecting layer 400. (A region) Thus, the etching to form the isolation structure 300 may proceed for the floating diffusion region protecting layer 400, and may not proceed for the floating diffusion region FD. The floating diffusion region protecting layer 400 may serve to prevent the etching from attacking or etching the floating diffusion region FD even if the etching is excessively performed without considering a margin in the crossroad region C during the etching process for forming the isolation structure 300.

The isolation structure 300 may include at least one among a silicon oxynitride (SiON) layer, a silicon oxide (SiO) layer, a silicon nitride (SiN) layer, and polysilicon (Poly Si).

The isolation structure 300 may be formed in a shape of being dug vertically deep so as to prevent a crosstalk, and may be formed through a deep trench isolation (DTI) process.

While various embodiments have been described above, variations and improvements of the disclosed embodiments and other embodiments may be made based on what is described or illustrated in this document.

I/We claim:

1. An image sensing device, comprising:
a substrate;
a photoelectric conversion element formed in the substrate;
an isolation structure disposed between the photoelectric conversion element and an additional photoelectric conversion element disposed adjacent to the photoelectric conversion element;
a floating diffusion region disposed above an upper portion of the isolation structure; and
a floating diffusion region protecting layer disposed below the floating diffusion region and contacting the upper portion of the isolation structure.

2. The image sensing device of claim 1,
wherein the floating diffusion region protecting layer comprises at least one of an oxide or a nitride.

3. The image sensing device of claim 1,
wherein a transfer transistor is disposed over the floating diffusion region.

4. The image sensing device of claim 1,
wherein the upper portion of the isolation structure is disposed to contact one region of the floating diffusion region protecting layer.

5. The image sensing device of claim 1,
wherein a width of the floating diffusion region protecting layer is greater than a width of the isolation structure.

6. The image sensing device of claim 1,
wherein a width of the floating diffusion region protecting layer is greater than or equal to a width of the floating diffusion region.

7. The image sensing device of claim 1,
wherein a height of the isolation structure is greater than a height of the floating diffusion region.

8. The image sensing device of claim 1,
wherein a width of the floating diffusion region protecting layer is greater than a width of the isolation structure and smaller than a width of the floating diffusion region.

9. The image sensing device of claim 1,
wherein the floating diffusion region protecting layer is formed above an upper portion of one side of the photoelectric conversion element.

10. The image sensing device of claim 1,
wherein the substrate has an etch selectivity that is different from an etch selectivity of the floating diffusion region protecting layer.

11. A method for manufacturing an image sensing device, comprising:
forming a first substrate;
forming a floating diffusion region protecting layer on the first substrate;
etching one region of the protecting layer;
forming a second substrate on the protecting layer;
forming a floating diffusion region in the second substrate; and
forming a transfer transistor above the floating diffusion region.

12. The method of claim 11, further comprising:
forming an isolation structure below the floating diffusion region protecting layer.

13. The method of claim 11,
wherein the floating diffusion region protecting layer comprises at least one or an oxide or a nitride.

14. The method of claim 12,
wherein the forming of the floating diffusion region protecting layer includes:
depositing material to form the isolation structure; and
etching a portion of the isolation structure.

15. The method of claim 12,
wherein an upper portion of the isolation structure is disposed to contact one region of the floating diffusion region protecting layer.

16. The method of claim 12,
wherein the forming of the isolation structure includes etching the first substrate.
